(19) United States
(12) Patent Application Publication
(10) Pub. No.: US 2026/0107434 A1
(43) Pub. Date: Apr. 16, 2026

(54) METHOD FOR MANUFACTURING SEMICONDUCTOR STRUCTURE

(71) Applicant: NANYA TECHNOLOGY CORPORATION, New Taipei City (TW)

(72) Inventor: Zih-Hong YANG, New Taipei City (TW)

(21) Appl. No.: 18/917,067

(22) Filed: Oct. 16, 2024

(51) Int. Cl. H10B 12/00

(52) U.S. Cl. CPC H10B 12/09

(57) ABSTRACT

A method for manufacturing a semiconductor structure includes the following steps. A substrate is received, in which the substrate has a functional area and a dummy area surrounding the functional area. A functional pattern is formed on the functional area and a dummy pattern is formed on the dummy area in a same process step. A closet distance between the dummy pattern and the functional pattern is from 15 nm to about 50 nm. The dummy pattern is removed.

### BACKGROUND

### Field of Invention

The present disclosure relates to a method for manufacturing a semiconductor structure. More particularly, the present disclosure relates to a method for manufacturing a semiconductor structure with a strengthened pattern edge.

### Description of Related Art

Lithography is a process that uses photoresist as a mask to create patterned structures. Therefore, the robustness of photoresist is of great importance to pattern definition. As advancing technology drives continuous size reduction, various technical problems arise. For example, some semiconductor structures cannot be successfully formed because of their miniaturized size.

Thus, there is a need to improve the semiconductor manufacturing process, particularly the lithography process.

### SUMMARY

One aspect of the present disclosure is to provide a method for manufacturing a semiconductor structure. The method includes the following steps. A substrate is received, in which the substrate has a functional area and a dummy area surrounding the functional area. A functional pattern is formed on the functional area and a dummy pattern is formed on the dummy area in a same process step. A closet distance between the dummy pattern and the functional pattern is from 15 nm to about 50 nm. Then, the dummy pattern is removed.

According to one or more embodiments, a density of the functional pattern is substantially equal to a density of the dummy pattern.

According to one or more embodiments, a material of the dummy pattern is the same as a material of the functional pattern.

According to one or more embodiments, a pattern of the functional pattern is different from a pattern of the dummy pattern.

According to one or more embodiments, a pattern of the functional pattern is the same as a pattern of the dummy pattern.

According to one or more embodiments, a line width of the functional pattern is less than 20 nm.

Another aspect of the present disclosure is to provide a method for manufacturing a semiconductor structure. The method includes the following steps. A substrate is received, in which the substrate has a functional area and a dummy area surrounding the functional area. A stacked layer is formed on the substrate. The stacked layer is patterned to form a bit line structure on the functional area and a dummy pattern on the dummy area. A closet distance between the dummy pattern and the bit line structure is from 15 nm to about 50 nm. The bit line structure is patterned to form a plurality of bit lines and a plurality of trenches surrounding the bit lines on the functional area. The dummy area is removed.

According to one or more embodiments, a density of the bit line structure is substantially equal to a density of the dummy pattern.

According to one or more embodiments, a pattern of the bit line structure is different from a pattern of the dummy pattern.

According to one or more embodiments, a pattern of the bit line structure is the same as a pattern of the dummy pattern.

According to one or more embodiments, a line width of each bit line is less than 20 nm.

According to one or more embodiments, the stacked layer includes an oxide layer, a poly silicon layer, a first nitride layer, a metal layer, and a second nitride layer stacked on the substrate sequentially from bottom to top.

According to one or more embodiments, each bit line includes an oxide layer, a poly silicon layer, a first nitride layer, a metal layer, and a second nitride layer stacked on the substrate sequentially from bottom to top.

According to one or more embodiments, the method further includes forming a filler material in the trenches to surround the bit lines.

According to one or more embodiments, a top surface of the filler material is leveled with top surfaces of the bit lines.

According to one or more embodiments, the patterning the bit line structure and the removing the dummy pattern are performed at a same step.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic top view illustrating a substrate according to some embodiments of the present disclosure.

FIG. 2 is an enlarged top view of the pattern in the region R in FIG. 1 according to some embodiments of the present disclosure.

FIG. 3 is an enlarged top view of the pattern in the region R in FIG. 1 according to another embodiment of the present disclosure.

FIG. 4 is an enlarged top view of the pattern in the region R’ according to a comparative example.

FIGS. 5-6 are schematic cross-sectional views of a semiconductor structure at various manufacturing stages according to some embodiments of the present disclosure.

FIG. 7 is a schematic top view illustrating a chop mask layer according to some embodiments of the present disclosure.

FIGS. 8-11 are schematic cross-sectional views of a semiconductor structure at various manufacturing stages according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined, all terms (including technical and scientific terms) used herein have the same meanings as those commonly understood by a person having ordinary skill in the art to which the embodiments of the present disclosure belong. It should be understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

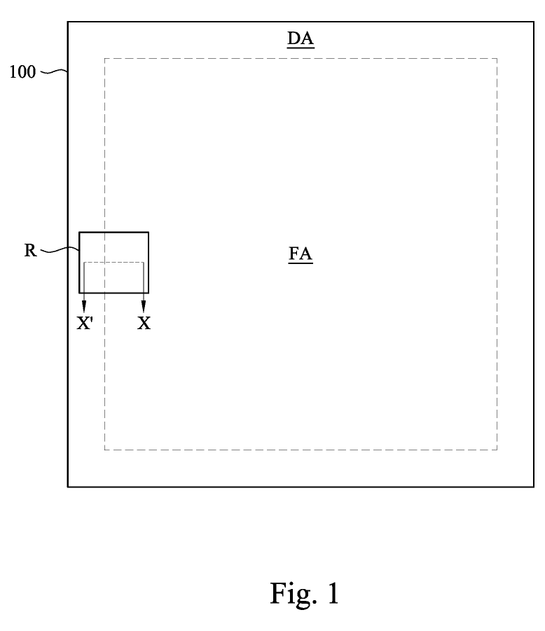

FIG. 1 is a schematic top view illustrating a substrate according to some embodiments of the present disclosure. One aspect of the present disclosure is to provide a method for manufacturing a semiconductor structure. The method includes the following steps.

Although a series of operations or steps are used below to describe the method disclosed herein, an order of these operations or steps should not be construed as a limitation to the present disclosure. For example, some operations or steps may be performed in a different order, and/or other steps may be performed at the same time. In addition, it is not necessary to perform all of the operations, steps, and/or features shown to achieve the embodiments of the present disclosure. In addition, each operation or step described herein may contain several sub-steps or actions.

As used herein, the terms “patterning” and “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer. The patterning process includes forming a mask on the existing film or layer and removing the unmasked film or layer with an etching or other removal process. The mask can be a photoresist or a hard mask. In some embodiments, a patterning process is adopted to form a patterned layer directly on a surface. The patterning process includes forming a photosensitive film on the surface, conducting a lithography process, and performing a developing process. The remaining photosensitive film is retained and integrated into the semiconductor device.

A substrate 100 is received, in which the substrate 100 has a functional area FA and a dummy area DA surrounding the functional area FA, as shown in FIG. 1.

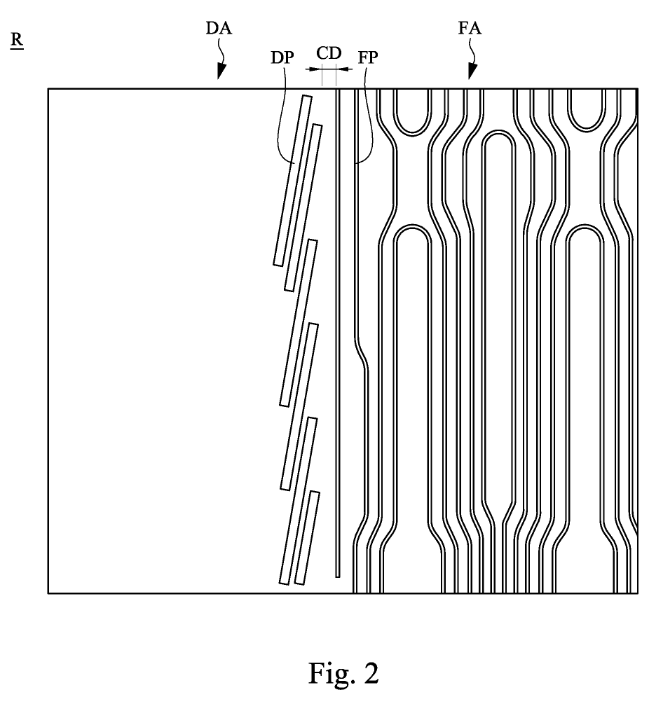

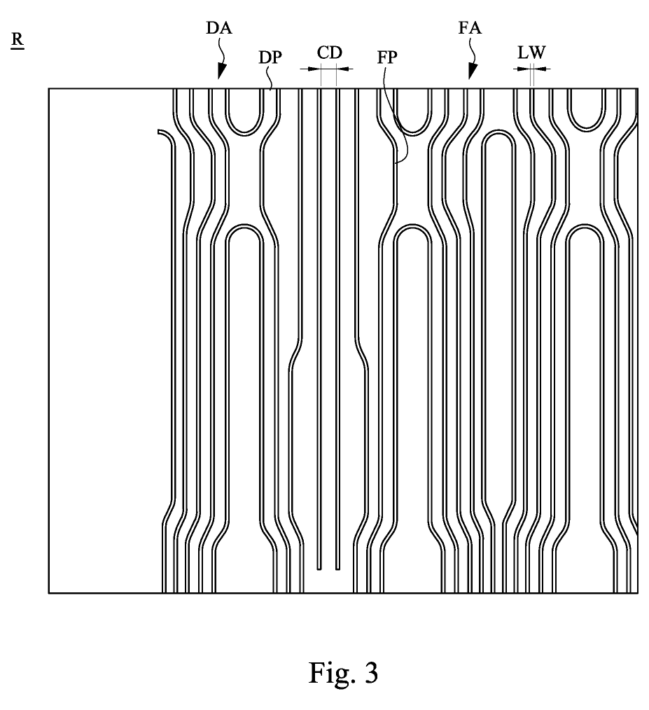

FIG. 2 is an enlarged top view of the pattern in region R in FIG. 1 according to some embodiments of the present disclosure. FIG. 3 is an enlarged top view of the pattern in the region R in FIG. 1 according to another embodiment of the present disclosure. Next, a functional pattern FP is formed on the functional area FA and a dummy pattern DP is formed on the dummy area DA in a same process step. It is noted that a closet distance CD between the dummy pattern DP and the functional pattern FP is from 15 nm to about 50 nm. For example, the closet distance CD between the dummy pattern DP and the functional pattern FP may be 20 nm, 25 nm, 30 nm, 35 nm, 40 nm, or 45 nm. The dummy pattern DP is then removed.

It can be understood that the etching load between the functional area FA and the dummy area DA can be balanced by designing the dummy pattern DP in the dummy area DA adjacent to the functional area FA to prevent an excessive difference in etching load between the two areas and defects in the functional pattern FP at the edge of the functional area FA, as shown in FIGS. 2-3. Therefore, the closet distance CD between the dummy pattern DP and the functional pattern FP is from 15 nm to about 50 nm. When the closet distance CD between the dummy pattern DP and the functional pattern FP is greater than a certain value, such as 50 nm, it is still impossible to reduce the etching load difference between the functional area FA and the dummy area DA. On the contrary, when the closet distance CD between the dummy pattern DP and the functional pattern FP is less than a certain value, such as 15 nm, it may cause etching incompleteness of the functional pattern.

According to one or more embodiments, a density of the functional pattern FP is substantially equal to a density of the dummy pattern DP. According to one or more embodiments, a pattern of the functional pattern FP is different from a pattern of the dummy pattern DP, as shown in FIG. 2. For example, the dummy pattern DP may include a straight line, a horizontal line, a diagonal line, a geometric pattern, an irregular pattern, or any suitable pattern, but not limited thereto. According to one or more embodiments, a pattern of the functional pattern FP is the same as a pattern of the dummy pattern DP, as shown in FIG. 3. According to one or more embodiments, a line width LW of the functional pattern FP is less than 20 nm. According to one or more embodiments, a material of the dummy pattern DP is the same as a material of the functional pattern FP.

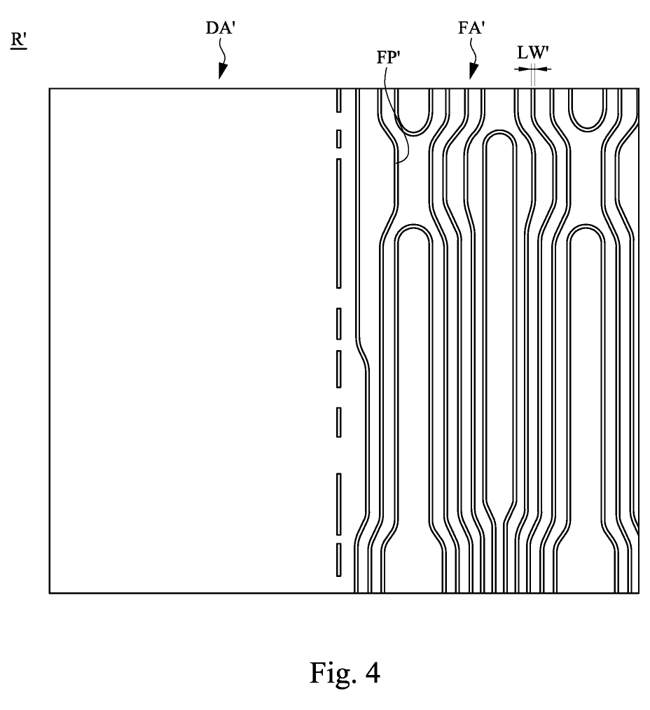

FIG. 4 is an enlarged top view of the pattern in region R’ according to a comparative example. In this comparative example, no dummy patterns are designed in the dummy area DA’. However, an etching process in the comparative example may not work successfully, especially with a shrinking technology node. As the line width LW’ becomes narrower, photoresist lines become more fragile. Specifically, the functional pattern FP’ at the edge of the functional area FA’ collapse after the etching process is performed. Since there is no dummy pattern in the dummy area DA’, the etching load in the functional area FA’ is much greater than that in the dummy area DA’, resulting in the etching non-uniformity. As the aspect ratio of the pattern increases, the impact of undercutting also increases, and pattern collapse becomes more likely to occur.

Another aspect of the present disclosure is to provide a method for manufacturing a semiconductor structure, such as a memory structure. In an advanced technology, process windows require more concerns. The array region and the peripheral region in a dynamic random-access memory (DRAM) cell have different pattern densities and serve different functions after the DRAM cell finishes its production process. Therefore, the process windows between the array region and the peripheral region vary significantly. Normally, their respective circuit patterns may not be formed at the same time.

In the multi-patterning process of semiconductors, such as self-aligned double patterning (SADP) or self-aligned quadruple patterning (SAQP), a chop mask layer needs to be formed to transfer key patterns to the wafer. For example, the metal zero (M0) layer is a critical layer because it is connected to multiple subsequent interconnect structures. In some embodiments, the fabrication of an M0 layer includes two separate processes, a peripheral region process and an array region process. The peripheral region process is used to form patterns in the peripheral region of a DRAM cell. The array region process is used to form patterns in the array region of a DRAM cell.

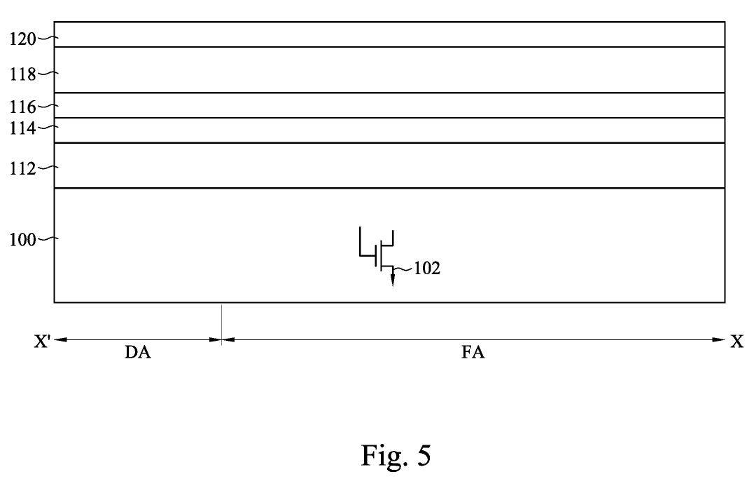

FIGS. 5-6 and 8-11 are schematic cross-sectional views taken along region R shown in FIG. 1 of the semiconductor structure at various manufacturing stages constructed. The method includes the following steps. Referring to FIG. 1, a substrate 100 is received, in which the substrate 100 has a functional area FA and a dummy area DA surrounding the functional area FA.

Please refer to FIG. 5. According to one or more embodiments, the substrate 100 may include at least one transistor 102 in the functional area FA. According to one or more embodiments, the substrate 100 may further include at least one landing pad (not shown) disposed on the transistor 102 in the functional area FA. In some embodiments, the landing pad is coupled to the gate of the transistor 102.

According to one or more embodiments, the substrate 100 may include a plurality of isolation areas (not shown) and a plurality of active areas (not shown). The active areas are spaced apart by the isolation areas. The isolation areas may be formed through a shallow trench isolation (STI) process. The isolation areas may include, for example, a material including at least one of silicon oxide, silicon nitride, and silicon oxynitride. The isolation areas may be a single layer including one kind of insulator, a double layer including two kinds of insulators, or a multilayer including a combination of at least three kinds of insulators. For example, the isolation areas may include silicon nitride and silicon oxide. For example, the isolation areas may include a triple layer including silicon oxide, silicon nitride, and silicon oxynitride.

According to one or more embodiments, the substrate 100 may include, for example, silicon (e.g., crystalline silicon, polycrystalline silicon, or amorphous silicon). In some embodiments, the substrate 100 may include other elementary semiconductor such as germanium. In some embodiments, the substrate 100 may include an alloy semiconductor such as silicon germanium, gallium indium phosphide, silicon germanium carbide and the like. In some embodiments, the substrate 100 may include compound semiconductor such as silicon carbide, gallium arsenic, indium phosphide, indium arsenide and the like. Further, the substrate 100 may optionally include a semiconductor-on-insulator (SOI) structure.

Referring to FIG. 5, a stacked layer is formed on the substrate 100. According to some embodiments, the stacked layer includes at least an oxide layer 112, a poly silicon layer 114, a first nitride layer 116, a metal layer 118, and a second nitride layer 120 stacked on the substrate 100 sequentially from bottom to top. According to one or more embodiments, the oxide layer 112, the poly silicon layer 114, the first nitride layer 116, the metal layer 118, and the second nitride layer 120 have planar top surfaces and planar bottom surfaces as shown in FIG. 5. In some embodiments, the metal layer 118 may include tungsten (W), aluminum (Al), cobalt (Co), copper (Cu), or other suitable metal or metal alloy. In some embodiments, the first nitride layer 116, also called a barrier layer, may be omitted. That is to say, the metal layer 118 may be direct contact with the poly silicon layer 114. In some embodiments, each layer of the stacked layer may be formed by a chemical vapor deposition, physical vapor deposition, sputtering, or the like. In some embodiments, each one of the stacked layer has a substantially flat surface.

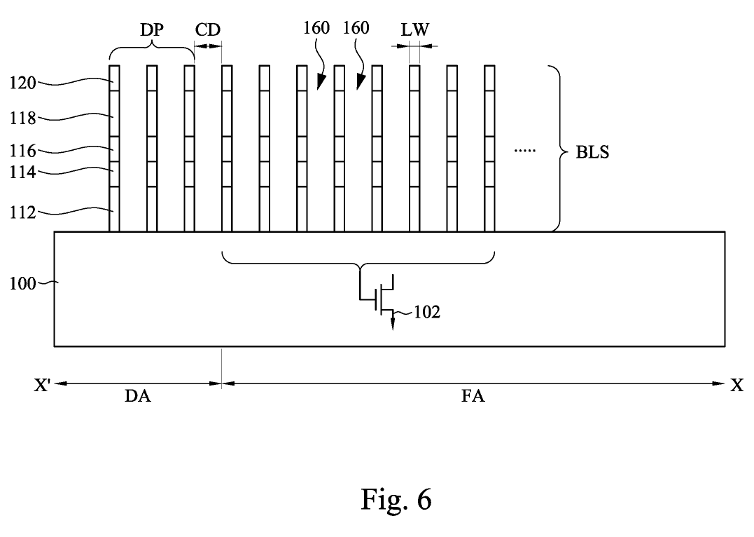

Referring to FIG. 6, the stacked layer is patterned to form a bit line structure BLS on the functional area FA and a dummy pattern DP on the dummy area DA. To be specific, the stacked layer is double patterned in the perpendicular substrate 100 direction. Double patterning may include, but not limited to, litho-etch-litho-etch (LELE) pitch-splitting or self-aligned double patterning (SADP). The bit line structure BLS herein is a continuous basic structure. In some embodiments, the material of the dummy pattern DP is the same with the material of the bit line structure BLS. More specifically, the dummy pattern DP includes the oxide layer 112, the poly silicon layer 114, the first nitride layer 116, the metal layer 118, and the second nitride layer 120 stacked on the substrate 100 sequentially from bottom to top. Similarly, the bit line structure BLS also includes the oxide layer 112, the poly silicon layer 114, the first nitride layer 116, the metal layer 118, and the second nitride layer 120 stacked on the substrate 100 sequentially from bottom to top.

It is noted that a closet distance CD between the dummy pattern DP and the bit line structure BLS is from 15 nm to about 50 nm. For example, the closet distance CD between the dummy pattern DP and the bit line structure BLS may be 20 nm, 25 nm, 30 nm, 35 nm, 40 nm, or 45 nm. When the closet distance CD between the dummy pattern DP and the functional pattern FP is greater than a certain value, such as 50 nm, it is still impossible to reduce the etching load difference between the functional area FA and the dummy area DA. On the contrary, when the closet distance CD between the dummy pattern DP and the functional pattern FP is less than a certain value, such as 15 nm, it may cause etching incompleteness of the functional pattern.

It should be noted that the bit line structure BLS and the dummy pattern DP are formed simultaneously. That is to say the bit line structure BLS and the dummy pattern DP are formed by using the same mask.

According to one or more embodiments, a density of the bit line structure BLS is substantially equal to a density of the dummy pattern DP. According to one or more embodiments, a pattern of the bit line structure BLS is different from a pattern of the dummy pattern DP as shown in FIG. 2. For example, the dummy pattern DP may include a straight line, a horizontal line, a diagonal line, a geometric pattern, an irregular pattern, or any suitable pattern, but not limited thereto. According to one or more embodiments, a pattern of the bit line structure BLS is the same as a pattern of the dummy pattern DP as shown in FIG. 3. According to one or more embodiments, a line width LW of the bit line structure BLS is less than 20 nm.

Next, the bit line structure BLS are patterned to form a plurality of bit lines BL and a plurality of trenches 160 surrounding the bit lines BL on the functional area FA. The dummy pattern DP on the dummy area DA is removed, as described in more detail below. According to one or more embodiments, the patterning the bit line structure BLS and the removing the dummy pattern DP are performed at a same step.

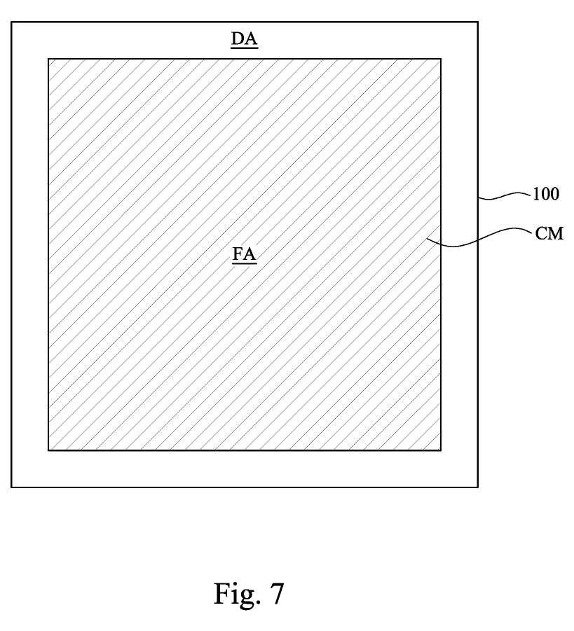

FIG. 7 is a schematic top view illustrating a chop mask layer according to some embodiments of the present disclosure. The chop mask layer CM shown in FIG. 7 is configured to define the dummy area DA and the functional area FA. The dummy area DA surrounds the functional area FA. As illustrated in FIG. 7, the chop mask layer CM includes at least a rectangle pattern, i.e., the rectangle pattern has a rectangle profile to define the functional area FA. The rectangle pattern corresponds to the functional area FA of the substrate 100 as shown in FIG. 1.

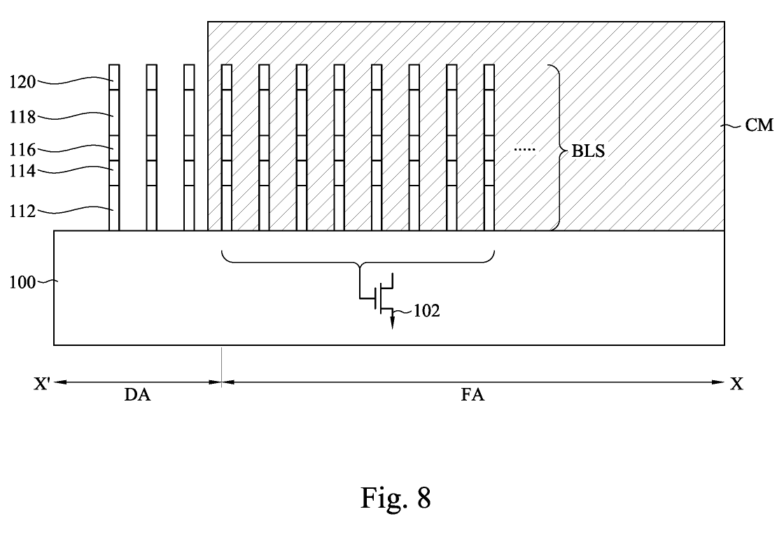

Referring to FIG. 8, the chop mask layer CM is formed over the substrate 100. Furthermore, the dummy pattern DP is exposed from the chop mask layer CM. More specifically, a plurality of portions of the bit line structure BLS is exposed from the chop mask layer CM (not shown).

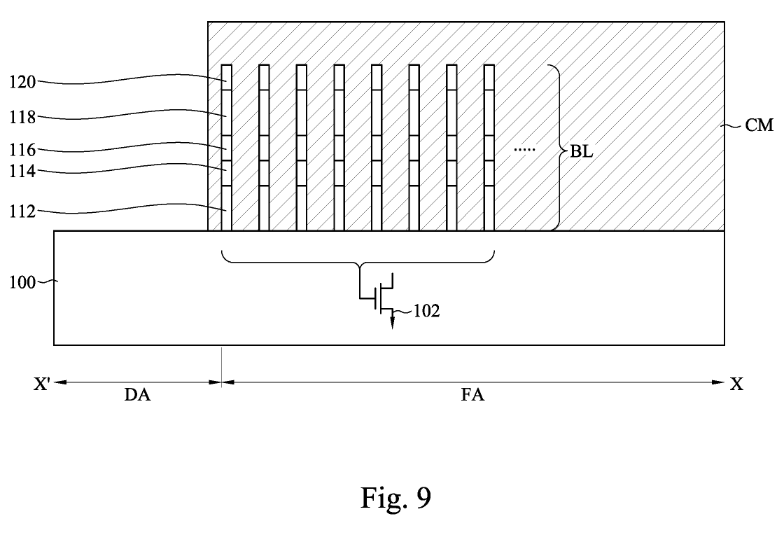

Referring to FIG. 9, the exposed dummy pattern DP and the exposed portions of the bit line structure BLS are removed. Therefore, there is no dummy pattern DP on the dummy area DA of the substrate 100, and the bit lines BL are formed on the functional area FA of the substrate 100, in which the bit lines BL are still covered by the chop mask layer CM.

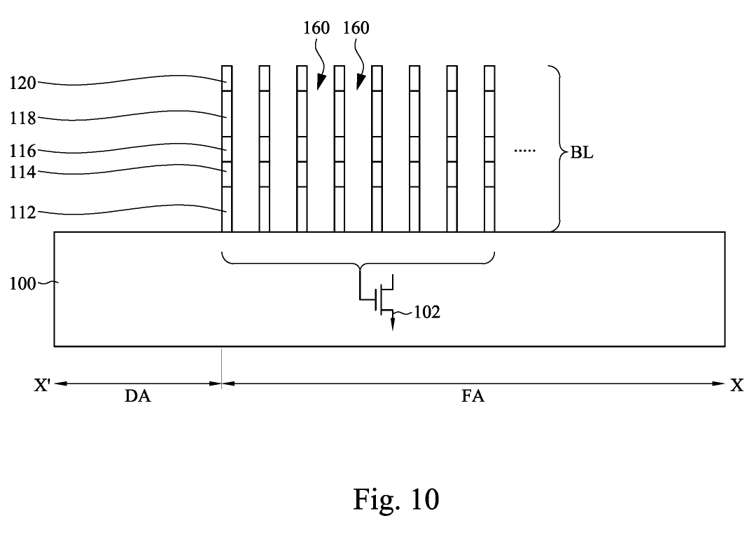

Referring to FIG. 10, the chop mask layer CM is removed, and trenches 160 are between adjacent bit lines BL. According to one or more embodiments, each bit line BL includes the oxide layer 112, the poly silicon layer 114, the first nitride layer 116, the metal layer 118, and the second nitride layer 120 stacked on the substrate sequentially from bottom to top. According to one or more embodiments, the bit lines BL are electrically coupled to the transistor(s) 102.

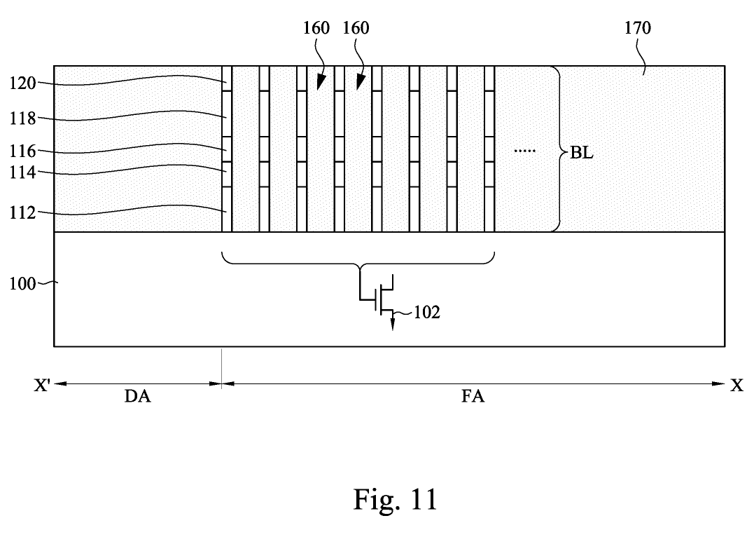

Referring to FIG. 11, a filler material 170 is formed in the trenches 160. To be specific, the filler material 170 surrounds the bit lines BL. In some embodiments, after the trenches 160 are filled with the filler material 170, a planarizing process (e.g., a chemical mechanical planarization) is performed. According to one or more embodiments, a top surface of the filler material 170 is leveled with top surfaces of the bit lines BL. In some embodiments, the filler material 170, such as CVD oxide, TEOS oxide, or other dielectric, is deposited into the trenches 160.

In some embodiments, at least one capacitor (not shown) is formed over the substrate 100. The capacitor includes a bottom electrode, a dielectric layer, and a top electrode. The dielectric layer includes high-K dielectric materials. The capacitor electrically connects to the gate of the transistor 102.

The above embodiments provide various advantages. The embodiments according to the disclosure disclose a self-aligned double patterning (SADP) technology to define functional pattern in the functional area of the substrate in a semiconductor structure. Due to the consideration of line width (less than 20 nm), the functional pattern (such as bit lines) need to undergo two lithographic processes and two etch processes. The adding of dummy patterns in the dummy area of the substrate fabrication bit lines on the M0 layer can increase the stability and integrity of peripheral bit line pattern. Therefore, the etching load between the functional area and the dummy area can be balanced by designing the dummy pattern in the dummy area adjacent to the functional area to avoid an excessive difference in etching load between the two areas and defects in the functional pattern at the edge of the functional area.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method for manufacturing a semiconductor structure, comprising:
receiving a substrate having a functional area and a dummy area surrounding the functional area;
forming a functional pattern on the functional area and forming a dummy pattern on the dummy area in a same process step, wherein a closet distance between the dummy pattern and the functional pattern is from 15 nm to about 50 nm; and
removing the dummy pattern.

2. The method for manufacturing the semiconductor structure of claim 1, wherein a density of the functional pattern is substantially equal to a density of the dummy pattern.

3. The method for manufacturing the semiconductor structure of claim 1, wherein a material of the dummy pattern is the same as a material of the functional pattern.

4. The method for manufacturing the semiconductor structure of claim 1, wherein a pattern of the functional pattern is different from a pattern of the dummy pattern.

5. The method for manufacturing the semiconductor structure of claim 1, wherein a pattern of the functional pattern is the same as a pattern of the dummy pattern.

6. The method for manufacturing the semiconductor structure of claim 1, wherein a line width of the functional pattern is less than 20 nm.

7. A method for manufacturing a semiconductor structure, comprising:
receiving a substrate having a functional area and a dummy area surrounding the functional area;
forming a stacked layer on the substrate;
patterning the stacked layer to form a bit line structure on the functional area and a dummy pattern on the dummy area, wherein a closet distance between the dummy pattern and the bit line structure is from 15 nm to about 50 nm;
patterning the bit line structure to form a plurality of bit lines and a plurality of trenches surrounding the bit lines on the functional area; and
removing the dummy pattern.

8. The method for manufacturing the semiconductor structure of claim 7, wherein a density of the bit line structure is substantially equal to a density of the dummy pattern.

9. The method for manufacturing the semiconductor structure of claim 7, wherein a pattern of the bit line structure is different from a pattern of the dummy pattern.

10. The method for manufacturing the semiconductor structure of claim 7, wherein a pattern of the bit line structure is the same as a pattern of the dummy pattern.

11. The method for manufacturing the semiconductor structure of claim 7, wherein a line width of each bit line is less than 20 nm.

12. The method for manufacturing the semiconductor structure of claim 7, wherein the stacked layer comprises an oxide layer, a poly silicon layer, a first nitride layer, a metal layer, and a second nitride layer stacked on the substrate sequentially from bottom to top.

13. The method for manufacturing the semiconductor structure of claim 7, wherein each bit line comprises an oxide layer, a poly silicon layer, a first nitride layer, a metal layer, and a second nitride layer stacked on the substrate sequentially from bottom to top.

14. The method for manufacturing the semiconductor structure of claim 11, further comprising:
forming a filler material in the trenches to surround the bit lines.

15. The method for manufacturing the semiconductor structure of claim 14, wherein a top surface of the filler material is leveled with top surfaces of the bit lines.

16. The method for manufacturing the semiconductor structure of claim 11, wherein the patterning the bit line structure and the removing the dummy pattern are performed at a same step.
